(19) United States
(12) Patent Application Publication
(10) Pub. No.: US 2006/0044057 A1
(43) Pub. Date: Mar. 2, 2006

(54) Class-D amplifier having high order loop filtering

(76) Inventors: Rahmi Hezar, Plano, TX (US); Baher Haroun, Allen, TX (US); Brett Forejt, Plano, TX (US); Srinath Ramaswamy, Dallas, TX (US)

Correspondence Address: TEXAS INSTRUMENTS INCORPORATED, P O BOX 655474, M/S 3999, DALLAS, TX, 75265, US

(21) Appl. No.: 10/928,528

(22) Filed: Aug. 26, 2004

(51) Int. Cl. H03F 3/38

(52) U.S. Cl. 330/10

(57) ABSTRACT

An amplifier having an active and passive gain stage connect to a load for driving a load according to a system analog input. A first embodiment of the amplifier in accordance with the present invention includes a logic network connected between a comparator network and a switching system, wherein the comparator network connects to the passive gain stage. Specifically, the active gain stage may include an active filter connected to receive an analog or digital input and provide a difference between the analog or digital input and the feedback signal relative to the gain factor of a gain unit connected to the active filter. The passive gain stage includes a passive filter. The logic network generates at least one switching signal which controls the switching system that includes at least one switching device to selectively provide power to the load. An output signal from the switching system provides output for the amplifier and is fed back to the active gain stage. In another embodiment, the output is a two-level signal and the passive and active filters are second order low pass filters, where the gain factor is about 25 or more. In yet another embodiment, the gain factor is approximately 250. Moreover, the amplifier may include a digital delta-sigma modulator connected to supply a two level input.

### COPENDING APPLICATIONS

This application is related to U.S. patent application Ser. No. 10/762,819, filed on Jan. 22, 2004, entitled AMPLIFIER USING DELTA-SIGMA MODULATION, the entirety of which is hereby incorporated by reference as if fully set forth herein.

### FIELD OF THE INVENTION

The present invention relates to amplifiers, and, more particularly, to a Class-D amplifier having high order loop filtering enabled to receive input from a digital-to-analog converter (DAC) and a delta-sigma modulation unit.

### BACKGROUND OF THE INVENTION

Audio annuciators are used in mobile and other communications devices, such as cell phones, speaker phones, etc. wherein an audio signal is amplified and provided to a speaker load. In applications such as cell phones and other mobile systems, the amplifier is powered by batteries, and hence power consumption is an important design consideration. Several driver or amplifier design choices are available for amplifying audio signals in such devices. Many mobile system amplifiers employ complementary transistor pairs or h-bridge networks to drive a speaker load. In class A, B, and AB amplifiers, the drive transistors are generally operated in a linear mode, whereas Class D amplifier transistors are switched between two distinct states (e.g. full on or full off).

Typical class AB amplifiers are capable of achieving respectable signal-to-noise plus distortions ratios (SNDR), for example, about 80 dB for audio applications, but have poor efficiency ratings, such as about 30 to 40% or less. For mobile applications, such as high quality multi-media and audio polyphonic ringers for laptop computers and mobile phones, the efficiency shortcomings of such amplifiers can lead to over-heating problems and excessive power consumption. Because of the switch mode operation, class D amplifiers offer power consumption efficiency advantages that are desirable in mobile phones and other battery-powered systems where audio amplification is needed. For example, for cell phones having an 8 OHM speaker load, class AB amplification can result in 600 mW power dissipation, while class D amplifiers may dissipate only about 40-50 mW.

FIG. 1. illustrates a conventional class D amplifier 10 for driving an audio load L (e.g., a speaker) using an H-bridge 30 with transistor switches SW1-SW4. The amplifier 10 includes an integrator 14 that receives a differential analog input signal 12 and a feedback signal form the h-bridge 30 and provides a differential input to plus terminals of two comparators 16a and 16b. The minus terminals of the comparators 16 are coupled with a triangle-wave input signal from a ramp generator 18, and the comparators provide a pair of pulse width modulated (PWM) signals to a logic circuit 20. The logic circuit 20 provides switching signals S1-S4 to the h-bridge 30 so as to selectively activate the switches SW1-SW4, respectively, whereby the load L is selectively coupled with positive and negative voltages V+ and V−, respectively.

Although consuming less power, class D amplifier such as the amplifier 10 in FIG. 1. suffer from low power supply rejection ratio (PSRR), thus requiring the addition of voltage regulation components for the power source that provides the amplifier power rails V= and V−. Furthermore, conventional class D amplifiers suffer from poor SNDR performance, typically in the 55 to 65 dB range with 0.05 to 0.10% power supply distortion. As shown in FIG. 1, the h-bridge 30 is prone to additive power supply noise from the supply rails V+ and V−, which is seen by the load L. In addition, the ramp generator 18 and the quantization noise of the comparators 16 create harmonic distortion at the load L. While providing the feedback from the load L to the integrator 14 helps alleviated the h-bridge distortion, this closed loop folds the harmonic noise of the PWM signals and the ramp generator 18 into the audio band, thus degrading the audio quality of the amplifier system 10. The integrator is typically limited to the first order filtering (e.g., single pole and zero) in order to avoid instability problems associated with second or higher order filtering, whereby the PSRR and SNDR capabilities of the conventional class D amplifier 10 are generally limited. Accordingly, there is a need for improved amplifiers that provide better efficiency, power supply noise rejection and signal-to-noise plus distortion rejection capabilities.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

To address the above-discussed deficiencies of the class D amplifier, the present invention teaches an amplifier circuit having an active and passive gain stage. A first embodiment of the amplifier in accordance with the present invention includes a logic network connected between a comparator network and a switching system, wherein the comparator network connects to the passive gain stage. Specifically, the active gain stage may include an active filter connected to receive an analog or digital input and provide a difference between the analog or digital input and the feedback signal relative to the gain factor of a gain unit connected to the active filter. The passive gain stage includes a passive filter. The logic network generates at least one switching signal which controls the switching system that includes at least one switching device to selectively provide power to a load. An output signal from the switching system provides output for the amplifier and is fed back to the active gain stage. In one example, the output is a two-level signal and the passive and active filters are second order low pass filters, where the gain factor is about 25 or more. In another example, the gain factor is approximately 250.

A second embodiment includes a delta-sigma modulator which connects to provide a two-level system analog input based on a digital system input to the active gain stage. Both embodiments of the invention may be employed in mobile phones and other situations in which low noise amplification is needed with minimal power consumption for creating audio or other powered signals, wherein power supply noise and harmonic distortion are passed through a filter system and corrected by a high gain amplifier. As a result, improved Class D and other amplifiers are achievable with superior PSRR and SNDR without significantly sacrificing the power consumption advantages of Class D amplifiers.

In one implementation, the switching system includes an h-bridge circuit. The passive and active filters are second order low pass filters in one example, wherein the invention facilitates high order filtering of power supply noise and other harmonic distortion from the h-bridge, and hence improved PSRR, whereby higher SNDR performance can be achieved while realizing the power consumption advantages of Class D amplification.

The following description and annexed drawings set forth in detail certain illustrative aspects and implementations of the invention. These are indicative of but a few of the various ways in which the principles of the invention may be employed.

### Brief Description of the Drawings

For a more complete understanding of the present invention and the advantages thereof, reference is now made to the following description taken in conjunction with the accompanying drawings in which like reference numbers indicate like features and wherein:

FIG. 1 is a schematic diagram illustrating a conventional Class D audio amplifier using pulse-width-modulation for powering a load;

FIG. 2 is a schematic diagram illustrating an exemplary fourth order delta-sigma based audio amplifier in accordance with the present invention;

FIG. 3 is a schematic diagram further illustrating the exemplary amplifier of FIG. 2;

FIGS. 4-5 are frequency response plots illustrating simulation results for the exemplary amplifier of FIGS. 2 and 3 in closed loop operation with no harmonic distortion, with harmonic distortion, respectively;

FIG. 6 is a schematic diagram illustrating an exemplary fourth order delta-sigma based audio amplifier having a digital delta-sigma modulator input in accordance with the present invention;

FIGS. 7-8 are frequency spectrum plots illustrating simulation results for the exemplary amplifier of FIG. 6 in closed loop operation with no harmonic distortion, with harmonic distortion, respectively;

FIG. 9 is a frequency spectrum plot illustrating simulation results for the exemplary amplifier of FIGS. 2 and 3 in closed loop operation with harmonic distortion and power supply noise; and

FIG. 10 is a frequency spectrum plot illustrating simulation results for the exemplary amplifier of FIGS. 2 and 3 in closed loop operation with harmonic distortion and noise levels for changing comparator noise.

### Detailed Description of Preferred Embodiments

One or more exemplary implementations of the present invention will now be described with reference to the attached drawings, wherein like reference numerals are used to refer to like elements throughout. The various aspects of the invention are illustrated below in an exemplary amplifier system 50 employing a passive delta-sigma modulator, with a high gain active filter provided in an outer feedback loop around the passive modulator, although the invention and the appended claims are not limited to the illustrated examples.

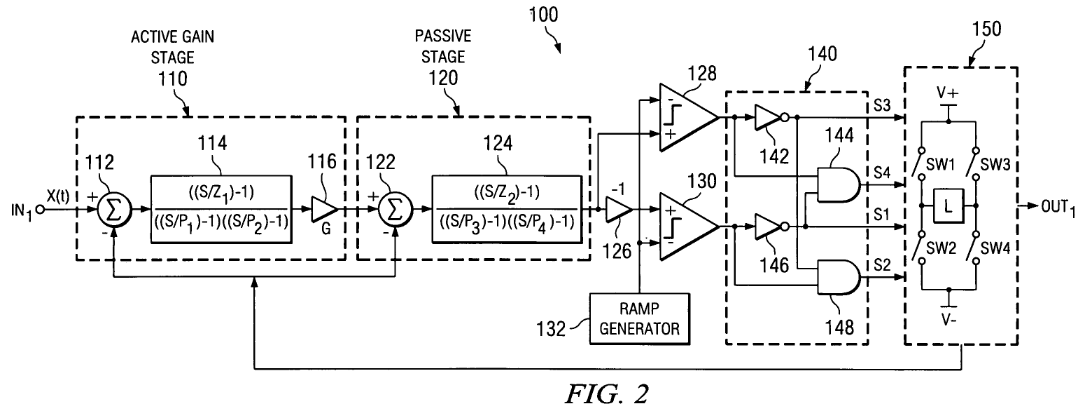

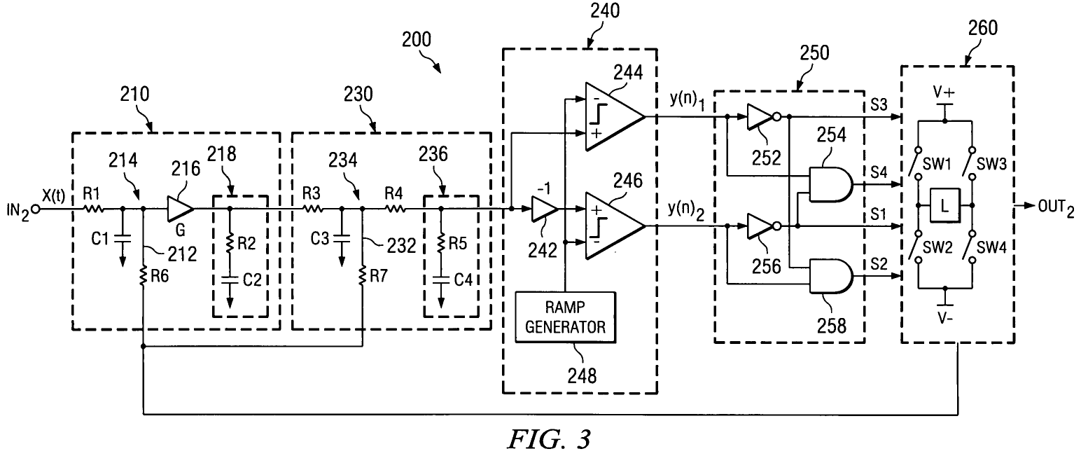

Referring to FIGS. 2 and 3, an exemplary delta-sigma based Class D audio amplifier system 10 is illustrated, comprising an active gain stage 110, a passive gain stage 120, a logic network 140, and a switching system 150 in a forward signal path of a passive delta-sigma converter stage or circuit. The active gain stage 110 comprises a summing junction 112, an active filter 114, a gain unit 116. The active filter 114 connects between the summing junction 112 and the gain unit 116. The passive gain stage 120 comprises a summing junction 122 and a passive filter 114 connected together. The active filter 114 and passive filter 124 are second order low pass filters. In one implementation, the poles of the active filter 114 are substantially matched with poles of the passive filter 124. The output of the passive gain stage 120 provides a differential input to plus terminals of two comparators 128 and 130, wherein the inverse of the output signal is provided through multiplier 126 to comparator 130. The minus terminals of the comparators 128 and 130 are coupled with a triangle-wave input signal from a ramp generator 132, and the comparators 128 and 130 provide a pair of pulse width modulated (PWM) signals to a logic circuit 140. The logic circuit 140 provides switching signals S₁-S₄ to the switching system 150. In one implementation, the switching system is an H-bridge circuit. The h-bridge 150 comprises first, second, third, and fourth transistor switching devices SW₁-SW₄, respectively, which are selectively activated (e.g., closed) via switching signals S₁-S₄, respectively, from the logic circuit 140. More particularly, the logic circuit 140 is connected to H-bridge circuit 150 so as to selectively activate the switches SW₁-SW₄, respectively, whereby the load L is selectively coupled with positive and negative voltages V+ and V−, respectively. All of the aforementioned elements are provided on the feed forward signal path of the amplifier. The feedback signal path connects to the summing junctions 112 and 122.

In operation, delta-sigma modulation is employed in driving an h-bridge or other switching circuit in audio amplification applications while performing a noise shaping function without significantly increasing power consumption, wherein noise power is spread over a bandwidth related to the modulator sampling frequency, thereby reducing the noise density in the band of interest. In addition, while conventional active delta-sigma modulators typically employ switched capacitor circuits, passive delta-sigma modulators can be employed to avoid switched capacitor leakage issues associated with modern CMOS fabrication processes. In the past, passive delta-sigma modulators and PWM-based Class D audio amplifiers have generally been restricted to lower order filters, wherein higher order filtering lengthens the loop delay, resulting in instability. In the exemplary amplifiers illustrated and described above, stable higher order filtering is achieved without significantly degrading amplifier efficiency.

The controlled activation of the switching devices SW₁-SW₄ provides selective coupling of the load L with positive and negative supply voltages V⁺ and V⁻, respectively. The first switching device SW₁, operates to selectively couple a first load terminal with V⁺, SW₂ selectively couples the first load terminal with V⁻, SW₃ selectively coupes a second load terminal with V⁺, and SW₄ selectively couples the second load terminal with V₁ according to the quantized output Y(n) via the switching signals S₁-S₄, respectively. Any switching system may be employed to selectively provide power to a load, wherein the present invention is not limited to the illustrated h-bridge configuration of the exemplary amplifier system 100. When modeled, the H-bridge circuit 150 has additive and multiplicative distortion plus the second harmonic. One of the tones is in-band and the other two are located around the sampling frequency such that these tones fold in-band when sampled. Typical values for the tone amplitudes are −40 dB and −60 dB, and for the second harmonic −60 dB and −80 dB.

As shown, the signal path consists of a four pole system that can filter out enough quantization noise at any high frequency from the input signal, wherein a two level digital delta-sigma modulated input signal can be used. The analog input of the class-D amplifier 100 can sample +V_{ref} or −V_{ref} depending on the level of the digital signal. In summary, the system 100 includes an active filter 110 having two poles, a zero, and a gain and a passive filter 120 having two poles and a zero. Advantages of this design includes but is not limited to a design having no clock, no sampling and no added jitter noise.

FIG. 3 illustrates a single-ended implementation of the audio amplifier system 110 from FIG. 2, although differential implementations are also possible within the scope of the invention. The amplifier system 200 receives a system analog input X(t) for conversion, and the comparator network 240 provides output Y(n)₁ and Y(n)₂ to the switching system 260 to drive the load L according to the input X(t). The passive filter 230 includes a summing junction or node 234 and a second order low pass filter 236, with two poles P₃ and P₄, as well as a zero Z₂, wherein the exemplary filter 236 is free of switching components to avoid leakage problems associated with switched capacitor circuits. As illustrated in FIG. 3, the pole P₃ is set by the values of resistor R3 and capacitor C3, the pole P₄ is set by the values of resistors R₄ and R₅, and capacitor C₅, and the zero Z₂ is set by the values of resistor R₅ and capacitor C₄. The feedback from the h-bridge circuit 260 is provided to the summing node 234 through resistor R₇ to provide a feedback signal 232 indicative of the current or voltage being applied to the load L.

The active filter stage 210 comprises a summing junction 214 and a second low pass filter 218, also free of switching components, as well as an amplifier 216, such as an operational amplifier or other amplifier circuit. While the amplifier 216 is illustrated in FIGS. 2 and 3 as a single component, any amplifier may be employed in accordance with the invention, which may be free of switching components in the forward signal path of the amplifier system 200. The amplifier 216, moreover, may include multiple components, for example, an operational amplifier with resistances in a feedback loop (not shown) to set the amplifier gain factor. In addition, the filter 218 may, but need not, be designed with poles and zero(s) corresponding to those of the first filter 230, wherein the amplifier 216 may be combined with the filter 218 in an active filter configuration that is free of switching components, as in the exemplary implementation of FIG. 3, within the scope of the invention.

The filter 210 is implemented without switching components, having two poles P₁ and P₂, as well as a zero Z₁, receiving the system analog input X(t) and providing the passive filter input according to the input X(t) and a feedback signal 212 through resistor R₆ that indicates the power applied to the load L, as illustrated in FIGS. 2 and 3. The pole P₁, is set by the values of resistor R₁ and capacitor C₁, the pole P₂ is set by the values of resistor R₂, the output impedance of the amplifier 216 and the capacitor C₂, and the zero Z₂ is set by the values of resistor R₂ and capacitor C₂. In the illustrated system 200, the passive and active filters, 210 and 230, are second order low pass filters, wherein poles of the active filter 210 may, but need not be substantially matched with poles of the passive filter 230. In one example described further below, the passive filter 230 has two poles, both of which are at about 100 kHz for audio amplification, with a zero at about 1.25 MHz, and the active filter 210 has poles at about 50 and 100 kHz and a zero at 1.25 MHz. The active stage gain may be any value, such as greater than about 25, preferably about 250 in the illustrated system 200.

The passive filter 230, comparator network 240, and the switching circuit 250 thus form a passive delta-sigma modulator providing a two-level output Y(n) used to selectively provide power to the load L. The active filter 210 provides a high gain outer feedback loop, and together with the passive delta-sigma modulator, forms a delta-sigma based amplifier driver system. The amplifier 200 and the driver system thereof provides fourth order noise shaping without the instability associated with known higher order PWM based Class D designs, by virtue of the filters 210 and 230, each of which is a second order low pass configuration in the system 200 (e.g., integrator). The closed loop configuration of the driver system provides filtering of power supply ripple and other noise in the h-bridge circuit 260, where such noise is fourth order noise shaped by the filters 210 and 230. As shown, the voltage on the H-bridge load L is fed back resistively. Although harmonic distortion associated with the triangle-wave signals typically found in PWM based amplifiers is not avoided, the amplifier in accordance with the present invention provides a more efficient amplifier system when compared with known higher order PWM based Class D designs. As a result, the amplifier 200 gain can be as high as 40-60 dB (GBW˜2.4 MHz). Thus, the system 200 attains the power efficiency advantages of Class D amplifier designs, while providing superior noise immunity (e.g., PSRR and SNDR performance) compared with conventional PWM-based amplifiers.

In operation, the passive filter 230 receives the filter stage analog input 70 and the first analog feedback signal 232 at the summing circuit 234, and provides a first filtered analog signal as an input signal to the comparator network 240 according to the difference between the filter stage input X(t) and the first feedback signal 232. The comparator network 240 provides the 2-level output Y(n) according to the first filtered analog signal, and the logic network 250 and switching circuit 260 provide the corresponding set of switching signals S₁-S₄ to drive the load L according to the quantized output Y(n), wherein the logic circuit 250 provides for smooth transitions between output states in the illustrated example. Moreover, in implementation, the carrier frequency may be 768 kHz.

The active stage receives the system input X(t) and provides the filter stage analog input X(t) through the second filter 218 and the amplifier 216 according to the difference between the system input X(t) and a second feedback signal 212 from the switching system 260 scaled by the gain factor of the amplifier 216. The amplifier 216 preferably has a high gain*bandwidth product, wherein the gain of the active filter 210 and the bandwidth of the filter poles are set according to the amplifier gain*bandwidth product and the desired frequency band for a given application. In the illustrated example, the poles and zeroes of the filters 236 and 218 generally correspond with one another, although strict pole and zero matching are not required within the scope of the invention. Further, the illustrated filters 210 and 230 are both second order low pass filters, although filters of other orders and other types (e.g., bandpass), may be used in accordance with the invention. Noise associated with harmonic distortion of the comparator network 240 is reduced by the gain factor of the amplifier 216, whereby the gain of the amplifier 216 is preferably high, such as greater than about 25, for example, about 250 in one implementation, although stable operation is believed to be possible with gains of 500 or more. In addition, the amplifier 200 may be adapted for use in a variety of applications across a wide bandwidth range, wherein the gain and pole/zero locations in the system 200 can be selected for any particular application.

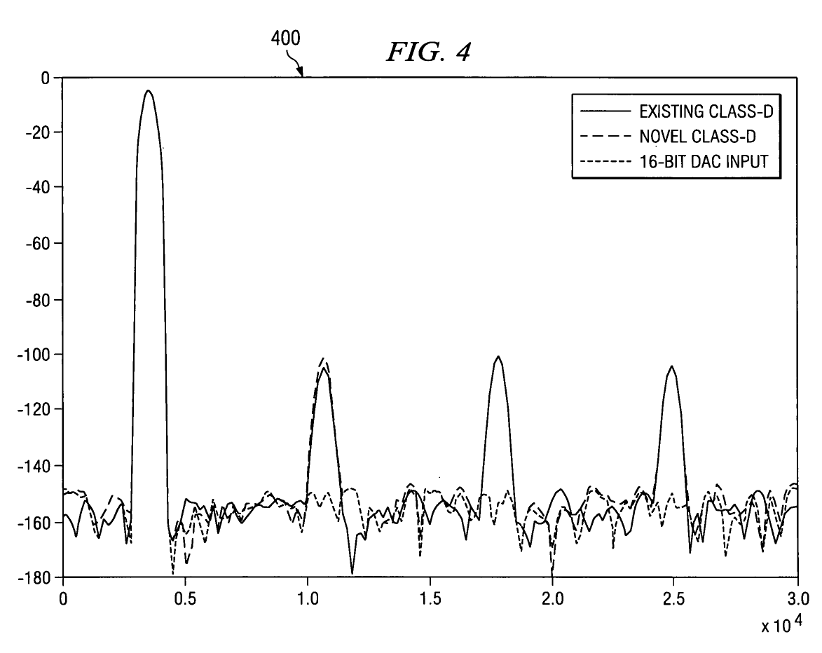

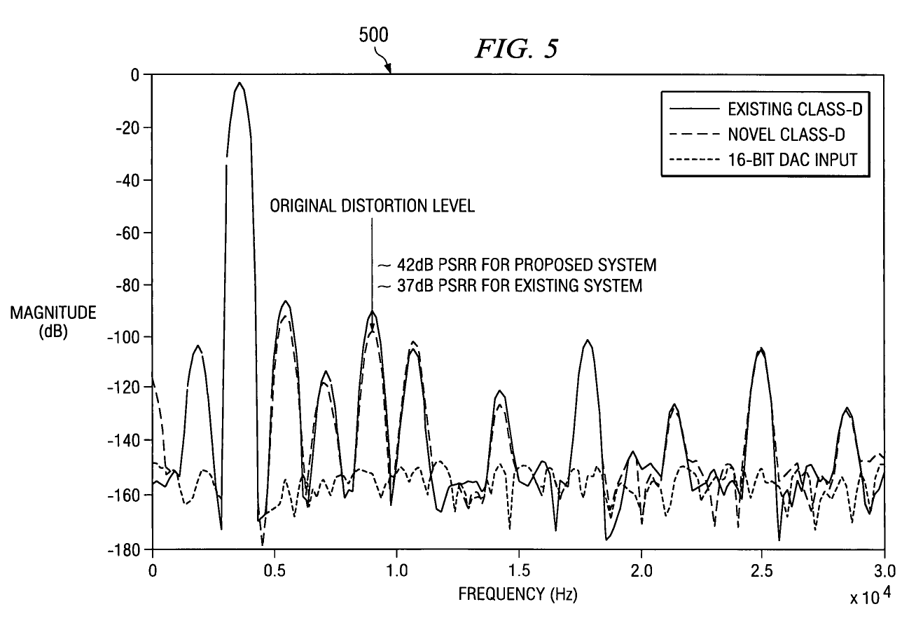

FIGS. 4-5 illustrate frequency spectrum plots 400 and 500 showing simulation results for the exemplary amplifier system 100 in open and closed loop operation without and with harmonic distortion, respectively. Specifically, the frequency spectrum is shown for the existing Class D amplifier, the improved Class-D amplifier 100 and a 16-bit DAC input. As shown in FIG. 4, without harmonic distortion from the H-bridge, performance is close for both systems, even around the three major harmonic. As shown in FIG. 5, with harmonic distortion from the H-bridge, however, the PSRR was greater for the amplifier system in accordance with the present invention as opposed to the know amplifier. Specifically, the amplifier in accordance with the present invention had a 42 dB PSRR as opposed to the 37 dB PSRR of the existing amplifier. In these simulations, the single tone was provided at the input X(t) at about 3.54 kHz at −3 dB in the audio band. The simulated performance results illustrate the effects of additive and multiplicative distortion, plus 2nd harmonic distortion for multiple tones, wherein three sine wave tones were used to model these noise sources. The H-bridge distortion of 5.4 K Hz, 24.5 MHz, and 12.2 MHz of −55 dB at approximately 2 mV were the specific additive and multiplicative distortion.

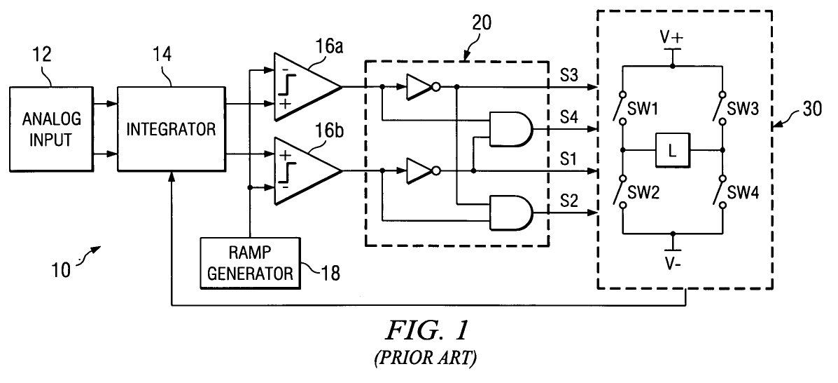

The following Table 1 illustrates simulated SNDR performance of the system 100 at various different noise conditions, as well as comparative results for the conventional PWM-based Class D amplifier design of FIG. 1, wherein the SNDR results are in dB and the switching numbers represent the total number of switching transitions at the h-bridge circuits, 30 and 150. Given that higher SNDR values indicate better noise immunity, when noise is present, the class-D amplifier 150 in accordance with the present invention out performs the known class-D amplifier 30, wherein HB represents h-bridge noise. Even at greater frequencies, amplifier 150 out-performs the known amplifier 30.

TABLE 1

| | SNDR | SNDR | SNDR |
|---|---|---|---|
| | 10 kHz BW | 20 kHz BW | 30 kHz BW |
| Digital Input Signal | 137 dB | 133 dB | 131 dB |
| Known Class D (no HB) | 136 dB | 96 dB | 93 dB |
| Novel Class D (no HB) | 136 dB | 95 dB | 94 dB |
| Known Class D (with HB) | 86.3 dB | 86.2 dB | 86.1 dB |
| Novel Class D (with HB) | 92 dB | 91 dB | 91 dB |

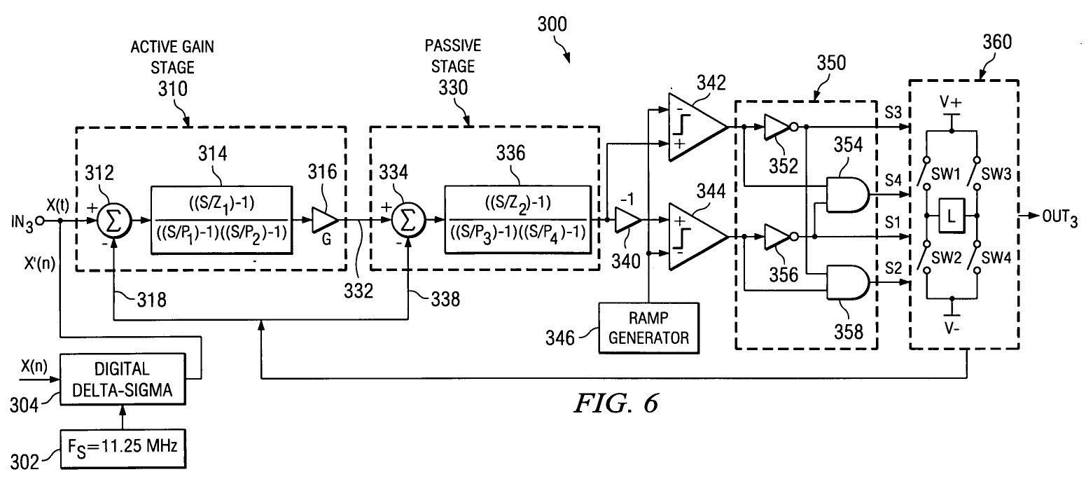

Shown in FIG. 6, another aspect of the invention involves providing a digital delta-sigma modulator (e.g., digital DSM) 304 at the input of the active filter 310. In a typical cell phone polyphonic ringer application, the amplifier input signal is an analog signal generated by a multi-level digital-to-analog converter (e.g., D/A or DAC), wherein the input information originates in a digital processing system in the cell phone. For high quality audio applications, a high performance DAC is required (e.g., an 8-bit DAC). The invention provides for reducing the number of levels, for example, from 8 or some other number, down to a two-level amplifier input using a digital DSM 304 as illustrated in FIG. 6, whereby no multi-level DAC is needed.

The exemplary 1-bit 3^{rd} order digital DSM 304 receives a multi-level digital input X(n), for example, an 8-bit signal from a digital system, and creates a 2-level digital output X′(n), which is provided as the driver system input to the active filter 310. The signal X(n) is summed with the digital DSM output feedback signal X′(n) at a summation node 312, and the difference is provided through a first gain stage 310 to a first filter and a second gain stage 330. The active stage 310 includes an active filter having two poles and a zero with a 40 dB gain. The resulting signal is summed at another summation node 334, together with an output feedback 338. As shown, the passive stage 330 includes a passive filter having two poles and a zero. As illustrated, because there are four poles and two zeros in the forward driver system signal path, any high frequency noise associated with the comparator 342 and 344 are noise shaped in the analog domain prior to the switching system 360. Thus, any such noise is not folded into the audio band. Furthermore, the expense and non-linearity of the conventional DAC is avoided.

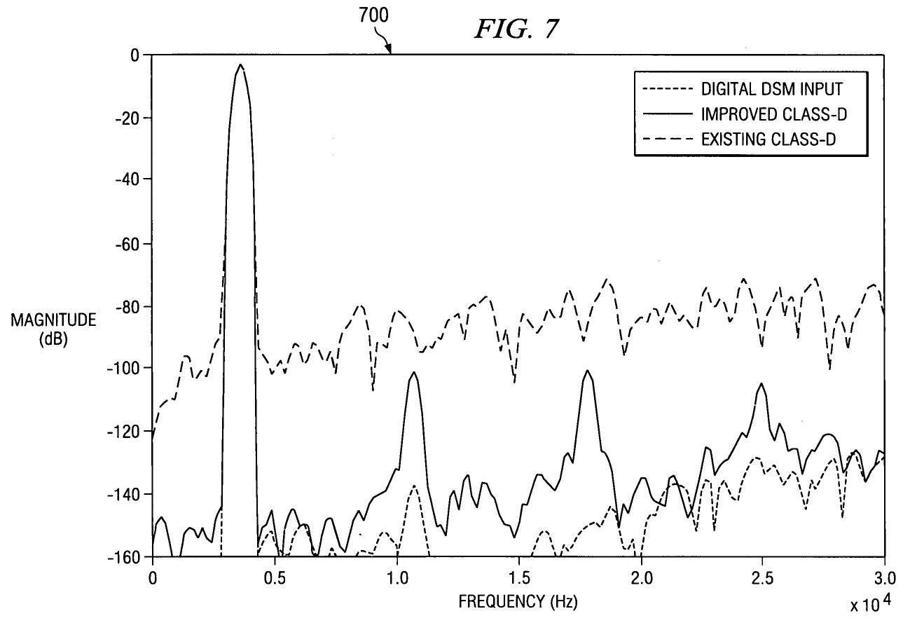

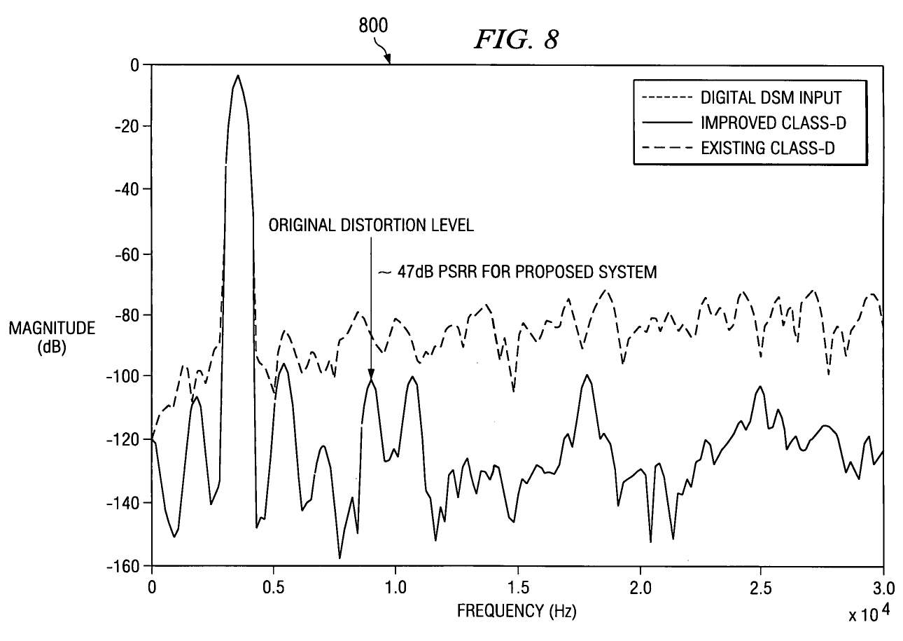

FIGS. 7-8 illustrate frequency spectrum plots 700 and 800 showing simulation results for the exemplary amplifier system 300 in open and closed loop operation without and with harmonic distortion, respectively. Specifically, the frequency spectrum is shown for the existing Class D amplifier, the improved Class-D amplifier 300 and a 16-bit DAC input. As shown in FIG. 7, without harmonic distortion from the H-bridge, performance of the improved class-D amplifier 300 is substantially greater than that of the known class-D amplifier 10. The known amplifier 10 has a higher noise floor due to mixing of the insufficiently filtered quantization noise with the 768 kHz PWM carrier. As shown in FIG. 8, with harmonic distortion from the H-bridge, performance of the improved class-D amplifier 300 lessens slightly but is still substantially greater than that of the known class-D amplifier 10. Similarly, the known amplifier 10 has a higher noise floor due to mixing of the insufficiently filtered quantization noise with the 768 kHz PWM carrier.

The following Table 2 illustrates simulated SNDR performance of the system 300 at various different noise conditions, as well as comparative results for the conventional PWM-based Class D amplifier design of FIG. 1, wherein the SNDR results are in dB and the switching numbers represent the total number of switching transitions at the h-bridge circuits, 30 and 360. Given that higher SNDR values indicate better noise immunity, when noise is present, the class-D amplifier 360 in accordance with the present invention out-performs the known class-D amplifier 30, wherein HB represents h-bridge noise. Even without noise, amplifier 360 has better noise immunity than amplifier 30. In addition, at greater frequencies, amplifier 360 out-performs the known amplifier 30.

TABLE 2

| | SNDR | SNDR | SNDR |
|---|---|---|---|
| | 10 kHz BW | 20 kHz BW | 30 kHz BW |
| Delta-Sigma Modulated Input | 140 dB | 131 dB | 116 dB |
| Existing Class D (no HB) | 75 dB | 65 dB | 61 dB |
| Novel Class D (no HB) | 129 dB | 95 dB | 94 dB |
| Existing Class D (with HB) | 73 dB | 63 dB | 59 dB |
| Novel Class D (with HB) | 92 dB | 91 dB | 91 dB |

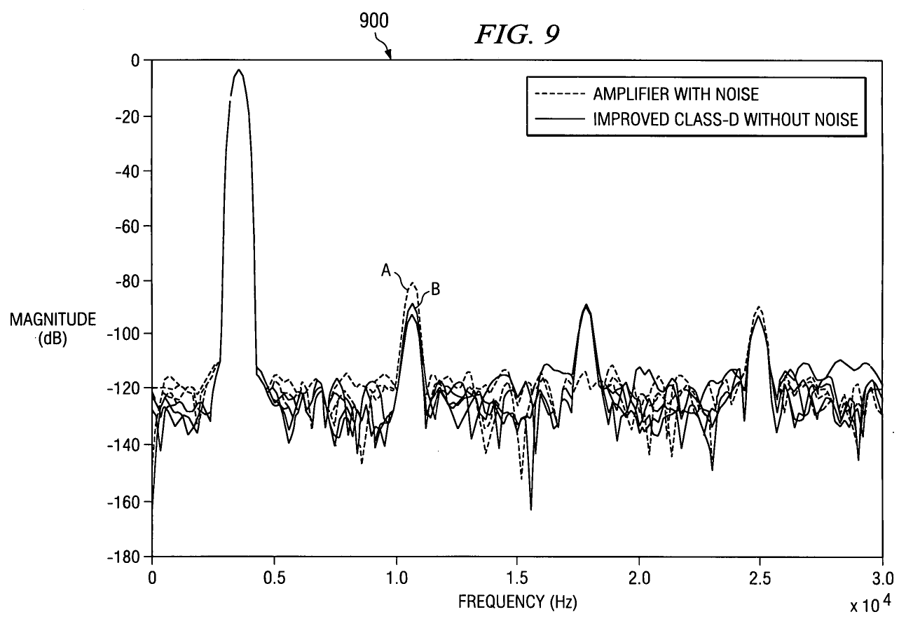

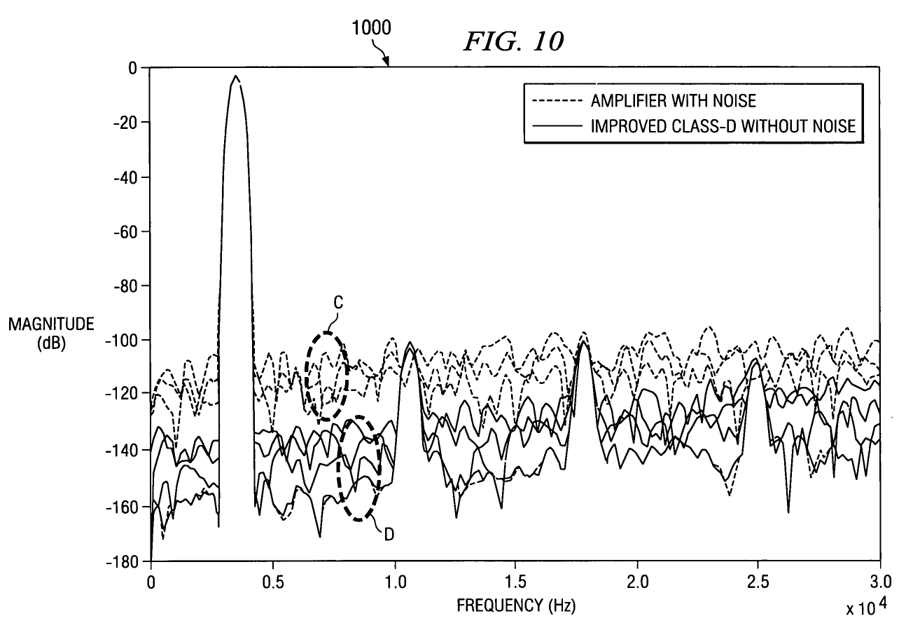

FIGS. 9-10 illustrate frequency spectrum plots 900 and 1000 showing simulation results for the known amplifier 10 and the exemplary amplifier system 100 in open and closed loop operation with noise, respectively. Specifically, noise includes harmonic distortion and random noise at the amplifier, comparator noise, comparator mismatch, and ramp noise. FIG. 9 displays with regard to amplifier 10, at point A, that due to the noise gives rise to a 3^{rd} harmonic increase, wherein the noise inserts an additional −60 dB level. At point B, the noise results in an additional −75 dB at the 3^{rd} harmonic. With regard to amplifier 100 in accordance with the present invention, point C represents the noise levels (25 nV-100 nV). As shown, the amplifier noise is not shaped thus it has more impact. In addition, the noise inserts an additional −60 dB at the 3^{rd} harmonic. Point D can be interpreted that the noise levels for changing the comparator noise (25 nV-100 nV) are shaped.

The following Table 3 illustrates simulated SNDR performance of the system 100 at various different noise conditions, as well as comparative results for the conventional PWM-based Class D amplifier design of FIG. 1, wherein the SNDR results are in dB and the switching numbers represent the total number of switching transitions at the h-bridge circuits, 30 and 150. In this regard, lower switching activity is desired for extended operational lifetime of the switching devices SW₁-SW₄ in the bridge circuits, 30 and 150, and higher SNDR values indicate better noise immunity. In these simulations, the ‘ideal’ cases correspond to no h-bridge noise, no amplifier or comparator noise, and no hysteresis, wherein HB represents h-bridge noise. As shown, the performance of the known amplifier 10 significantly drops, since the high frequency quantization noise on the digital input is not sufficiently filtered. As a result, the digital input is modulated by the PWM and fed back to the system increasing the noise floor. The performance of amplifier 100 is unchanged due to the high order filtering of the input signal.

TABLE 3

| | | | | Class -D system w/DSM in | | |
|---|---|---|---|---|---|---|
| | Existing Class -D system | | | accordance with the | | |
| | (8-bit ideal DAC) | | | present invention | | |
| | SNDR | SNDR | SNDR | SNDR | SNDR | SNDR |
| | 10 KHz | 20 KHz | 30 KHz | 10 KHz | 20 KHz | 30 KHz |
| | BW | BW | BW | BW | BW | BW |
| No noise, no distortion | 108.3 | 84.8 | 83.4 | 138.6 | 95.2 | 94.7 |
| Comp. noise = 25 nV/√Hz | 108 | 84.2 | 83 | 128.2 | 95.2 | 94.7 |
| Comp. noise = 50 nV/√Hz | 107 | 84.1 | 82.9 | 120.7 | 94.7 | 94.2 |
| Comp. noise = 100 nV/√Hz | 104.5 | 83.2 | 81 | 117.9 | 94.1 | 93.9 |
| Amp. noise = 25 nV/√Hz | 104.2 | 83.2 | 81.5 | 104.9 | 93.1 | 91.3 |
| −75 dB 3^{rd} harmonic | | | | | | |
| Amp. noise = 50 nV/√Hz | 100 | 83 | 81.5 | 97.2 | 89.5 | 86.7 |
| −75 dB 3^{rd} harmonic | | | | | | |
| Amp. noise = 100 nV/√Hz | 95.3 | 82.4 | 81.2 | 92.4 | 85.5 | 82 |
| −75 dB 3^{rd} harmonic | | | | | | |
| Amp. noise = 25 nV/√Hz | 104.5 | 77.4 | 76.8 | 104.8 | 93 | 91.2 |
| −60 dB 3^{rd} harmonic | | | | | | |
| Comp. mismatch = −60 dB | 107.6 | 84 | 82.9 | 138.5 | 95.2 | 94.7 |
| Comp. mismatch = −40 dB | 107.1 | 83.1 | 81.9 | 138.5 | 95.2 | 94.7 |
| Comp. mismatch = −20 dB | 106.9 | 83 | 81 | 138.5 | 95.2 | 94.7 |
| Ramp noise = 25 nV/√Hz | 107.8 | 84.1 | 82.9 | 128.2 | 95.1 | 94.6 |
| Ramp noise = 25 nV/√Hz | 107.1 | 83.2 | 81.9 | 123.1 | 94.9 | 94.3 |
| ALL noise (−60 dB 3^{rd} harm.) | 103.8 | 77.3 | 76.7 | 103.9 | 92.2 | 90.8 |
| ALL noise + HB distortion | 81.3 | 75.9 | 75.5 | 87.3 | 86.3 | 86 |

The reader's attention is directed to all papers and documents which are filed concurrently with this specification and which are open to public inspection with this specification, and the contents of all such papers and documents are incorporated herein by reference.

All the features disclosed in this specification (including any accompany claims, abstract and drawings) may be replaced by alternative features serving the same, equivalent or similar purpose, unless expressly stated otherwise. Thus, unless expressly stated otherwise, each feature disclosed is one example only of a generic series of equivalent or similar features.

The terms and expressions which have been employed in the foregoing specification are used therein as terms of description and not of limitation, and there is no intention in the use of such terms and expressions of excluding equivalents of the features shown and described or portions thereof, it being recognized that the scope of the invention is defined and limited only by the claims which follow.

What is claimed is:

1. An amplifier, comprising:
an active gain stage that comprises,
an active filter coupled to a gain, the active filter coupled to receive an analog input and to provide a difference between the analog input and the feedback signal relative to the gain factor,
a passive gain stage coupled to the active gain stage, that comprises,
a passive filter coupled to the active filter to produce a passive filter output signal;
a comparator network coupled to the passive gain stage;
a logic network coupled to the comparator network to generate at least one switching signal; and
a switching system comprising at least one switching device to selectively provide power to a load, the switching system controlled by the logic network output to provide an output signal for the amplifier, wherein a feedback signal is equivalent to the output signal, the feedback signal is applied to the active gain stage.

2. The amplifier of claim 1, wherein the active filter comprises:
a summing junction coupled to receive the analog input and to subtract the feedback signal therefrom;
a low pass filter, wherein the transfer function of the low pass filter has one zero and two poles; and
a gain unit.

3. The amplifier of claim 1, wherein the passive filter comprises:
a summing junction coupled to the active filter, to subtract the feedback signal therefrom; and
a low pass filter, wherein the transfer function of the low pass filter has one zero and two poles.

3. The amplifier of claim 1, wherein the comparator network comprises:
a ramp signal generator to produce a ramp signal;
a first comparator coupled to receive the ramp signal and the passive filter output signal to provide a difference between the ramp signal and the passive filter output signal in a first comparator network output signal;
a multiplier coupled to receive the passive filter output signal to generate an inverted passive filter output signal; and
a second comparator coupled to receive the ramp signal and the inverted passive filter output signal to provide a difference between the ramp signal and the inverted passive filter output signal in a second comparator network output signal.

4. The amplifier of claim 1, wherein the logic network comprises:
a first inverter, having an input and an output, the input coupled to receive the first comparator network output signal, wherein the output provides the first switching signal;
a first AND gate, having a first and second input and an output, the first input coupled to receive the first comparator network output signal, wherein the output provides the second switching signal;
a second inverter, having an input and an output, the input coupled to receive the second comparator network output signal, wherein the second input of the first AND gate couples to the output of the second inverter, wherein the output provides the third switching signal;
a second AND gate, having a first and second input and an output, the first input coupled to receive the second comparator network output signal, the second input coupled to the output of the first inverter, wherein the output provides the fourth switching signal.

5. The amplifier of claim 1, wherein the H-bridge circuit including a first and second power supply voltage, an output, and a load, the h-bridge circuit comprising:
a first switching device selectively coupling a first load terminal with the first power supply voltage, wherein the first switching device couples to receive the first switching signal;
a second switching device selectively coupling the first load terminal with the second power supply voltage, wherein the second switching device couples to receive the second switching signal;
a third switching device selectively coupling a second load terminal with the first power supply voltage, wherein the third switching device couples to receive the third switching signal; and
a fourth switching device selectively coupling the second load terminal with the second power supply voltage, wherein the fourth switching device couples to receive the fourth switching signal.

6. The amplifier of claim 3, wherein the ramp signal generator is a triangular ramp signal generator.

7. The amplifier of claim 4, wherein the logic network asserts the first and fourth switching signals when the amplifier is in first state, the logic network asserts the second and third switching signals when the amplifier is in second state.

8. The amplifier of claim 5, wherein the output from the H-bridge circuit is a two-level signal.

9. The amplifier of claim 1, wherein the passive and active filters are second order low pass filters.

10. The amplifier of claim 9, wherein poles of the active filter are substantially matched with poles of the passive filter.

12. The amplifier of claim 2, wherein the gain unit has a gain factor of about 25 or more.

13. The amplifier of claim 2, wherein the gain unit has a gain factor of about 250.

14. The amplifier of claim 1, further comprising a digital delta-sigma modulator providing a two-level system analog input to the driver system.

15. The amplifier of claim 14, wherein the passive and active filters are second order low pass filters.

16. The amplifier of claim 15, wherein poles of the active filter are substantially matched with poles of the passive filter.

17. The amplifier of claim 14, wherein the gain unit has a gain factor of about 25 or more.

18. The amplifier of claim 14, wherein the gain unit has a gain factor of about 250.
